(19) United States
(12) Patent Application Publication
(10) Pub. No.: US 2007/0017699 A1
(43) Pub. Date: Jan. 25, 2007

(54) Circuit board

(75) Inventors: Toshio Ishimoto, Echizen-shi (JP); Toshihiko Sasaki, Echizen-shi (JP); Naofumi Okayama, Echizen-shi (JP); Masayoshi Terashima, Echizen-shi (JP)

Correspondence Address: REED SMITH LLP, Suite 1400, 3110 Fairview park Drive, Falls Church, VA, 22042, US

(73) Assignee: Orion Electric Company Ltd.

(21) Appl. No.: 11/486,028

(22) Filed: Jul. 14, 2006

(30) Foreign Application Priority Data
Jul. 20, 2005 (JP) 2005-209705

(51) Int. Cl. H05K 1/11; H05K 1/18

(52) U.S. Cl. 174/260; 174/264

(57) ABSTRACT

A pair of through holes are formed in a circuit board, and a silver paste filled up in the through holes connects lands formed on a front surface and a rear surface of the circuit board, respectively to each other. When the silver paste is solidified, the silver paste bulges curvedly from the front and rear surfaces of the circuit board and forms a bump. A surface of the bump is covered with an overcoat. An electronic component is brought into contact with the bump, thereby forming a degassing gap between the electronic component and the circuit board. A gas generated during soldering is discharged from the penetrating hole, into which the lead terminal is inserted, to an outside via the gap between the electronic component and the circuit board.

### BACKGROUND OF THE INVENTION

1. Field of the Invention

The present invention relates to a circuit board configured so that a lead terminal of an electronic component is soldered to a wiring pattern formed on the circuit board by a dip soldering method and the like while the lead terminal is inserted and mounted into the wiring pattern, thereby electrically connecting the wiring pattern to the electronic component. More specifically, the present invention relates to a circuit board configured to effectively discharge a gas generated during soldering.

2. Description of the Related Art

If an electronic circuit of various types is to be formed, then a predetermined circuit is formed by forming a wiring pattern on a circuit board consisting of an insulating material, and an electronic component is connected to the wiring pattern, thereby mounting the electronic component on the circuit board. The electronic component thus mounted on the circuit board has a lead terminal inserted into a penetrating hole formed in the wiring pattern and soldered to the wiring pattern.

As a method for connecting the lead terminal to the wiring pattern, there is known dip soldering. In the dip soldering, the circuit board is dipped in a solder dipping bath and transported while the lead terminal of the electronic component is inserted into a penetrating hole of the circuit board and temporarily stopped. A lower surface of the circuit board is successively brought into contact with a solder jet formed in the solder dipping bath, thereby soldering the lead terminal to the wiring pattern.

At the time of soldering the lead terminal to the wiring pattern by the dip soldering, a flux is evaporated through contacting with a solder jet to generate a gas. This gas sometimes remains in the penetrating hole into which the lead terminal is inserted. If the gas remains in the penetrating hole during the soldering, molten solder is often filled up in the penetrating hole insufficiently. If so, in a process of manufacturing the circuit board, the gas remaining in the penetrating hole is heated and expanded, and cracking occurs to the solder, which causes soldering defects. Conventionally, measures have been taken to prevent the soldering defects following the generation of the gas at a soldering step. For instance, Japanese Patent Application Laid-Open No. 2002-57430 discloses a printed circuit board configured as follows. A support bump is formed on a mount surface of a circuit board by screen printing using a silk ink. An electronic component mounted on the circuit board is supported by the support bump, thereby forming a degassing gap between the circuit board and the electronic component. Japanese Patent Application Laid-Open No. 2004-55798 discloses an electronic component soldering structure configured as follows. A wiring pattern, a resist layer, and a silkscreened layer are formed on a circuit board. An extraction pattern is formed so that a surface of the circuit board is exposed with a part of the silkscreened layer left. A gap is formed by the extract ion pattern on a bottom of an electronic component arranged on the silkscreened layer.

With the configuration in which the support bump that supports the electronic component is formed by the silkscreened layer printed on the circuit board or in which the degassing gap is formed between the electronic component and the circuit board by the extraction pattern from which the silkscreened layer is extracted, as disclosed in Japanese Patent Application Laid-Open Nos. 2002-57430 and 2004-55798, the degassing gap is formed by an extremely thin silkscreened layer. Therefore, there is a limit to a width of the gap. As a result, it is disadvantageously impossible to form a gap that can effectively discharge the gas and a degassing efficiency is disadvantageously deteriorated.

### SUMMARY OF THE INVENTION

The present invention has been achieved to solve the conventional disadvantages. It is an object of the present invention to provide a circuit board that can effectively discharge a gas generated at a soldering step and that can further ensure soldering.

According to a first aspect of the present invention, there is provided a circuit board on which a wiring pattern for electrically connecting an electronic component to the circuit board is formed, a penetrating hole being formed in the wiring pattern, a lead terminal of the electronic component being inserted into the penetrating hole, thereby electrically connecting the lead terminal to the wiring pattern, wherein a plurality of through holes are formed in the circuit board, lands are formed on a front surface and a rear surface of the circuit board so as to be located around an opening of each of the through holes, a conductive paste filled up in the through holes connects the respective lands to each other, a curvedly bulging bump is formed out of the conductive paste on at least a mounting surface on which the electronic component is mounted, and the electronic component is brought into contact with the bump covered with an insulating layer, thereby forming a degassing gap between the circuit board and the electronic component.

According to a second aspect of the present invention, there is provided the circuit board according to the first aspect, wherein the lands are separated from the wiring pattern and electrically isolated from the wiring pattern.

According to a third aspect of the present invention, there is provided the circuit board according to the first or second aspect, wherein the lead terminal of the electronic component is soldered to the wiring pattern of the circuit board by dip soldering method while the lead terminal is inserted and mounted into the wiring pattern, thereby electrically connecting the wiring pattern to the electronic component, and the through holes are arranged in a transport direction of the circuit board during soldering so that the through holes are not overlapped with an extension of the penetrating hole.

According to a fourth aspect of the present invention, there is provided the circuit board according to any one of the first to third aspects, wherein an overcoat is formed on a surface of the bump as the insulating layer, and a surface of the overcoat is further covered with a silkscreened layer.

According to a fifth aspect of the present invention, there is provided the circuit board according to any one of the first to fourth aspects, wherein an extraction pattern, from which a resist layer and the wiring pattern formed on the circuit board are extracted, is formed around the penetrating hole to be located on the mounting surface on which the electronic component is mounted, and ends of the extraction pattern are extended to an outside of the electronic component.

According to the circuit board in the first aspect of the present invention, a flux is applied to the circuit board at a prior step to the dip soldering so as to improve solderability at the time of performing a soldering treatment on the circuit board. When the circuit board applied with the flux is subjected to the soldering treatment, the flux is evaporated and a gas is generated. The gas enters the penetrating hole into which the lead terminal of the electronic component is inserted. If the electronic component mounted on the circuit board is, for example, a quartz oscillator having a flat bottom, the bottom of the electronic component is closely attached to the circuit board. As a result, the gas entering the penetrating hole is not discharged from the penetrating hole. However, by forming the curvedly bulging bump on the circuit board out of the conductive paste, and by contacting the electronic component mounted on the circuit board with this bulge, the gap that communicates with the penetrating hole is formed between the circuit board and the electronic component. It is thereby possible to efficiently discharge the gas generated during soldering from the penetrating hole to the outside of the electronic component via the gap between the electronic component and the circuit board, and prevent soldering defects caused by the gas.

According to the circuit board in the second aspect of the present invention, the lands for forming the bulges are electrically isolated from the wiring pattern that connects the electronic component to the circuit board. It is, therefore, possible to prevent such an electric failure as short-circuit.

According to the circuit board in the third aspect of the present invention, when the gas generated during soldering is discharged from the penetrating hole to the outside of the electronic component via the gap between the circuit board and the electronic component, the gas can be smoothly discharged to the outside of the electronic component without disturbing a flow of the gas.

According to the circuit board in the fourth aspect of the present invention, the height of the bump is increased by the overcoat and the silkscreened layer and the gap between the circuit board and the electronic component resulting from the bump can be set wide. It is, therefore, possible to efficiently discharge the gas generated during soldering to the outside of the electronic component via the gap between the electronic component and the circuit board.

According to the circuit board in the fifth aspect of the present invention, the extraction pattern from which the wiring pattern and the resist layer are extracted is formed on an inlet side on which the gas is discharged from the penetrating hole to the gap between the circuit board and the electronic component. The extraction pattern enables the gap to be set wide. It is, therefore, possible to efficiently discharge the gas generated during soldering to the outside of the electronic component via the gap between the electronic component and the circuit board.

### BRIEF DESCRIPTION OF THE DRAWINGS

FIG. 1 is a cross-sectional view of a circuit board according to a first embodiment of the present invention;

FIG. 2 is a plan view of the circuit board according to the first embodiment;

FIG. 3 is an explanatory view of a soldering step according to the first embodiment;

FIGS. 4A and 4B are explanatory views of a positional relationship between penetrating holes and through holes at the soldering step according to the first embodiment;

FIG. 5 is a cross-sectional view of a circuit board according to a second embodiment of the present invention;

FIG. 6 is a plan view of the circuit board according to the second embodiment; and

FIGS. 7A and 7B are explanatory views of a positional relationship between penetrating holes and through holes at the soldering step according to the second embodiment.

### DESCRIPTION OF THE PREFERRED EMBODIMENTS

Most preferred embodiments of the present invention will be described hereinafter with reference to the accompanying drawings. Needless to say, the present invention is readily applicable to circuit boards other than those described in the embodiments within a range of the spirit or scope of the invention.

### First Embodiment

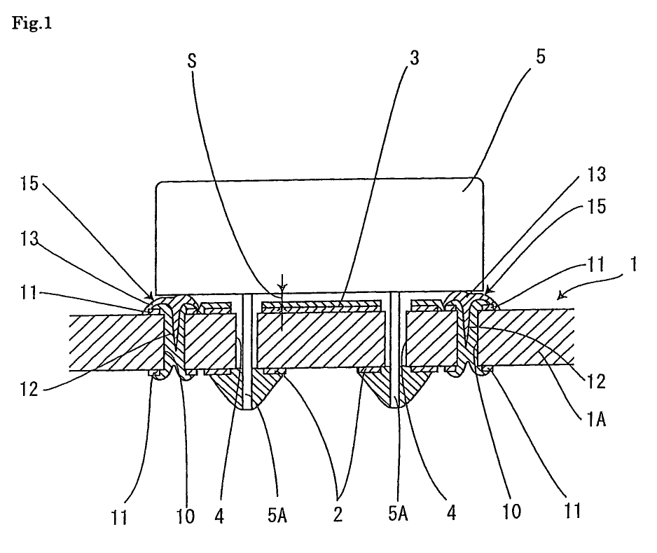

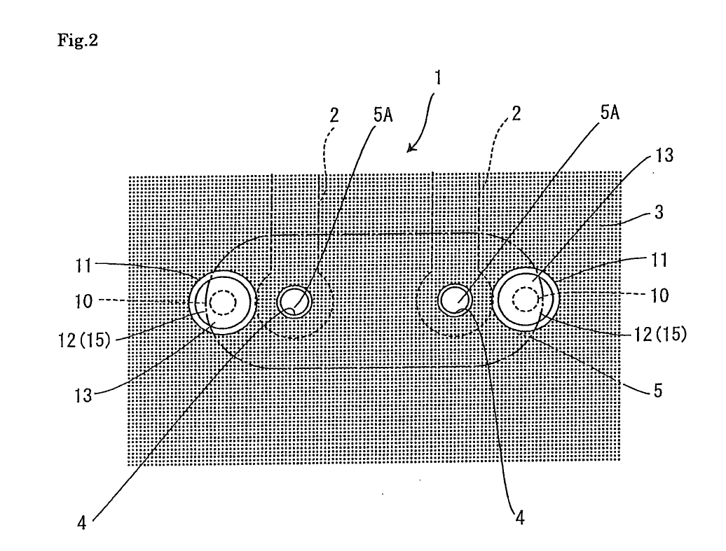

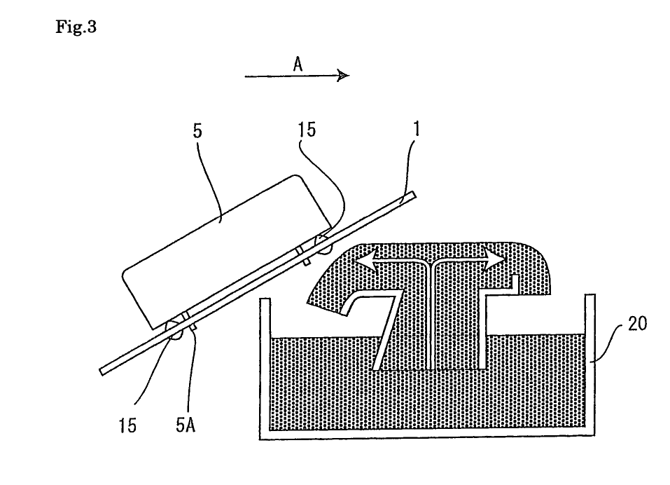

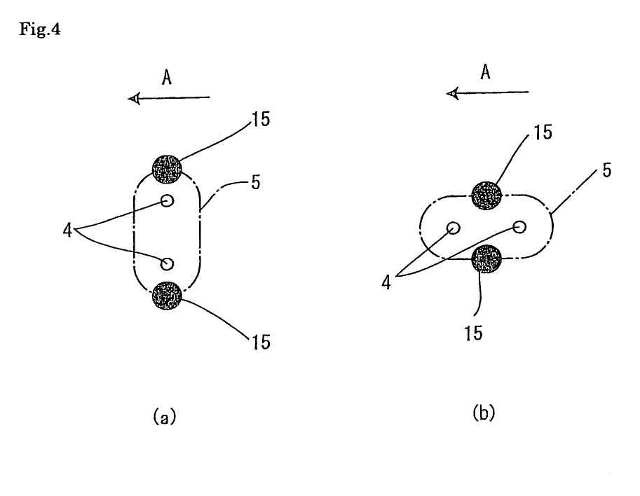

FIGS. 1 to 4A and 4B depict a first embodiment of the present invention. FIG. 1 is a cross-sectional view of a circuit board according to the first embodiment of the present invention. FIG. 2 is a plan view of the circuit board. FIG. 3 is an explanatory view of a soldering step. FIGS. 4A and 4B are explanatory views of a positional relationship between penetrating holes and through holes at the soldering step according to the first embodiment. In FIGS. 1 to 4A and 4B, reference symbol 1 denotes a circuit board. The circuit board 1 is configured as follows. Copper foils are laminated on a front surface and a rear surface of an insulating substrate 1A consisting of, for example, a copper-clad laminate containing paper and phenol resin, respectively. Unnecessary copper foils are removed by photoetching or the like, thereby forming a desired wiring pattern 2. Thereafter, a resist layer 3 is printed on an unsoldered part, and penetrating holes 4 are formed in the wiring pattern 2. Lead terminals 5A of an electronic component 5 inserted into the respective penetrating holes 4 are soldered to the wiring pattern 2, thereby electrically connecting the circuit board 1 to the electronic component 5.

A pair of through holes 10 are formed in the circuit board 1. Lands 11 each consisting of the copper foil are formed to be located around an opening of each of the through holes 10 on a front surface and a rear surface of the circuit board 1, respectively. A conductive paste, which is a silver paste 12 in this embodiment, is filled up in each through hole 10, and the lands 11 on the front and rear surfaces of the circuit board 1 are connected to each other by this silver paste 12. As stated, each through hole 10 is filled with the molten silver paste 12 to thereby electrically connect the lands 11 formed on the front and rear surfaces of the circuit board 1. When the silver paste 12 that connects the lands 11 is solidified, the silver paste 12 bulges curvedly from the front and rear surfaces of the circuit board 1. The curvedly bulging silver paste 12 forms a bump 15 that contacts with the electronic component 5. In addition, a surface of the bump 15 is covered with an overcoat 13, which serves as an insulating layer, on the front surface of the circuit board 1 which surface is a mounting surface on which the electronic component 5 is mounted. By thus contacting the bump 15 covered with the overcoat 13 with the electronic component 5 mounted on the circuit board 1, a degassing gap S of 10 to 50 μm is formed between the electronic component 5 and the circuit board 1. The positional relationship between the through hole 10 filled with the silver paste 12 and the penetrating hole 4 into which the lead terminal 5A is penetrated is such that the through hole 10 is not overlapped with the penetrating hole 4 in a transport direction A of the circuit board 1 at a soldering step to be described later. The lands 11 and the wiring pattern 2 formed on the rear surface of the circuit board 1 are separated so as to be electrically isolated from each other.

Each lead terminal 5A is connected to the wiring pattern 2 by soldering the lead terminal 5A thereto by dip soldering method. As shown in FIG. 3, a jet pump (not shown) is incorporated into a dipping bath 20, and the molten solder is circulated in the bath 20 so as to flow out by this jet pump. The circuit board 1, which is a workpiece, is transported to the dipping bath 20 by a carrier (not shown). The circuit board 1 is applied with a flux at a prior step to the soldering step, and transported by the carrier to be moved upward of the dipping bath 20. During transport, the circuit board 1 is suspended and dipped in the dipping bath 20, thereby soldering the lead terminals 5A of the electronic component 5 to the wiring pattern 2 of the circuit board 1 by the dip soldering. After this soldering step, the circuit board 1 is drawn up from the dipping bath 20 by the carrier, and moved to a next cooling step.

The flux is applied to the circuit board 1 at the prior step to the dip soldering so as to improve a solderability of the solder at the time of performing a soldering treatment on the circuit board 1. If the workpiece or the circuit board 1 applied with the flux is dipped in a solder bath, a chemical reaction occurs between the flux and the molten solder to generate a gas. In addition, the gas thus generated enters the penetrating holes 4 into which the respective lead terminals 5A of the electronic component 5 are inserted. If the electronic component 5 mounted on the circuit board 1 is, for example, a quartz oscillator having a flat bottom, the bottom of the electronic component 5 is closely attached to the circuit board 1. As a result, the gas that enters the penetrating holes 4 is not discharged from the holes 4. In this embodiment, the through holes 10 are formed in the circuit board 1, the silver paste 12 filled up in the through holes 10 forms a pair of curvedly bulging bumps 15. The electronic component 5 mounted on the circuit board 1 is brought into contact with the bumps 15 to thereby form a gap S that communicates with the penetrating holes 4 between the circuit board 1 and the electronic component 5. By so forming, the gas generated at the soldering step is effectively discharged to the outside from the through holes 4 via the gap S between the electronic component 5 and the circuit board 1. As stated, the degassing gap S is formed between the electronic component 5 and the circuit board 1. By forming the bump 15 out of the silver paste 12 that connects the lands 11 formed on the front and rear surfaces of the circuit board 1 to each other, and by covering the surface of the bump 15 with the overcoat 13, a width of the degassing gap S can be set large as compared with a structure in which the gap is formed simply by the thin resist layer, the wiring pattern and the like. It is, therefore, possible to effectively discharge the gas generated at the soldering step. Furthermore, since the bumps 15 bulge curvedly from the circuit board 1, a contact area between each bump 15 and the electronic component 5 can be suppressed to be small. In addition, each of the through holes 10 filled with the silver paste 12 is located at such a position at which the through hole 10 is not overlapped with the penetrating hole 4 in the direction A in which the molten solder flows at the soldering step. Therefore, the gas is smoothly discharged from the gap S to the outside without disturbing a flow of the gas that is released from the penetrating holes 4 to the outside via the gap S. It is thereby possible to ensure that the electronic component 5 is soldered to the circuit board 1 and prevent soldering defects. Besides, since the lands 11 formed on the rear surface of the circuit board 1 are electrically isolated from the wiring pattern 2, such an electric failure as short-circuit can be prevented.

### Second Embodiment

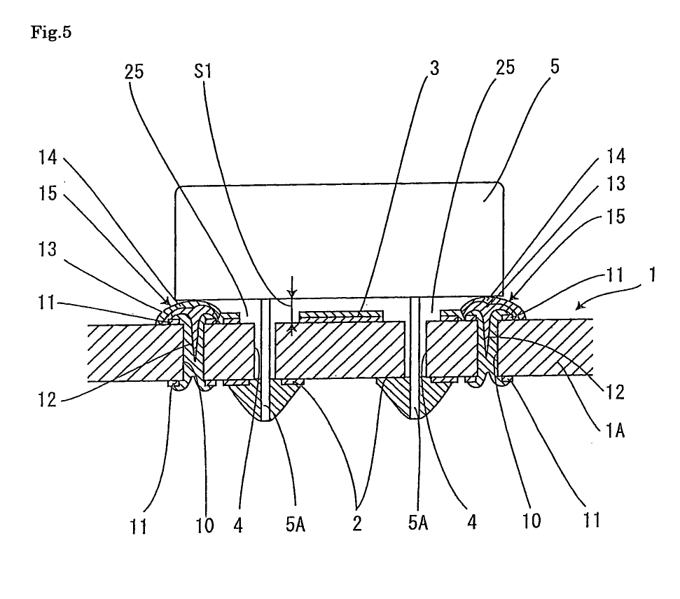

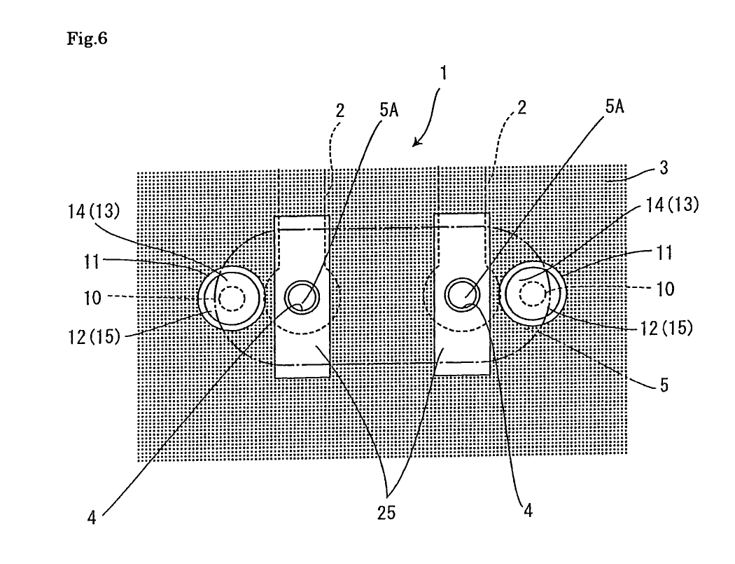

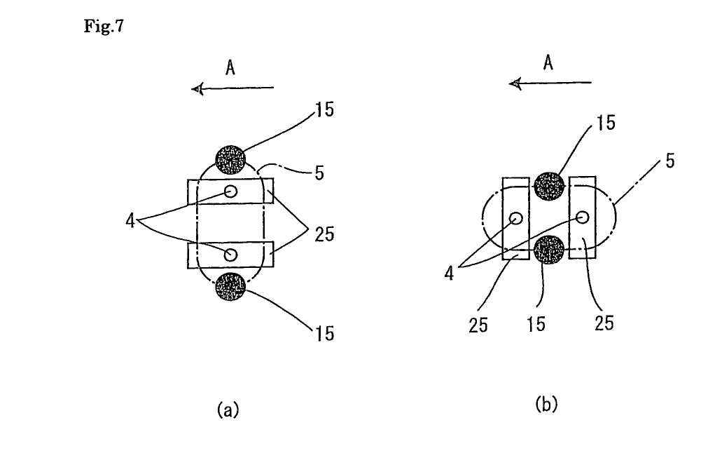

FIGS. 5 to 7A and 7B depict a second embodiment of the present invention. FIG. 5 is a cross-sectional view of a circuit board according to the second embodiment of the present invention. FIG. 6 is a plan view of the circuit board. FIGS. 7A and 7B are explanatory views of a positional relationship between penetrating holes and through holes at a soldering step. In FIGS. 5 to 7A and 7B, the same elements as those shown in FIGS. 1 to 4A and 4B are denoted by the same reference symbols and will not be repeatedly described herein. Therefore, only different elements from those according to the first embodiment will be described herein. In this embodiment, a surface of the overcoat 13 that covers up the surface of each bump 15 is further covered with a silkscreened layer 14. By doing so, a height of each bump 15 (that is, the width of the gap S1) can be set larger than that according to the first embodiment. In addition, an extraction pattern 25 from which the wiring pattern 2 and the resist layer 3 are extracted to expose the insulating substrate 1A is formed on the front surface of the circuit board 1 which surface is the mounting surface on which the electronic component 5 is mounted. Ends of the extraction pattern 25 are extended to the outside of the electronic component 5.

As stated, according to the second embodiment, the surface of the overcoat 13 that covers up the surface of each bump 15 is further covered with the silkscreened layer 14. The height of the bump 15 can be thereby set larger than that according to the first embodiment. It is, therefore, possible to further widen a gap S1 between the circuit board 1 and the electronic component 5 and to more effectively perform degassing. In addition, the extraction pattern 25 from which the wiring pattern 2 and the resist layer 3 are extracted is formed on the surface of the circuit board 1 which surface is the mounting surface on which the electronic component 5 is mounted. Therefore, the gap S1 between the circuit board 1 and the electronic component 5 on the extraction pattern 25 can be greatly widened to 80 to 135 μm. Besides, by extending the ends of the extraction pattern 25 to the outside of the electronic component 5, the gas generated at the soldering step can be effectively discharged from the penetrating holes 4 to the outside via the extraction pattern 25 and the gap Si. It is thereby possible to ensure that the electronic component 5 is soldered to the circuit board 1 and prevent soldering defects similarly to the first embodiment.

Although the embodiments of the present invention have been described so far in detail, the present invention is not limited to these embodiments. Various modifications can be made without departing from the spirit or scope of the invention. For instance, in the embodiments, the quartz oscillator has been described as an example of the electronic component mounted on the circuit board. Alternatively, an electronic component other than the quartz oscillator can be employed. In addition, the number of bumps and the number of lead terminals may be arbitrarily set.

1. A circuit board on which a wiring pattern for electrically connecting an electronic component to the circuit board is formed, a penetrating hole being formed in the wiring pattern, a lead terminal of the electronic component being inserted into the penetrating hole, thereby electrically connecting the lead terminal to the wiring pattern, wherein
a plurality of through holes are formed in the circuit board,
lands are formed on a front surface and a rear surface of the circuit board so as to be located around an opening of each of the through holes,
a conductive paste filled up in the through holes connects the respective lands to each other,
a curvedly bulging bump is formed out of the conductive paste on at least a mounting surface on which the electronic component is mounted, and
the electronic component is brought into contact with the bump covered with an insulating layer, thereby forming a degassing gap between the circuit board and the electronic component.

2. The circuit board according to claim 1, wherein
the lands are separated from the wiring pattern and electrically isolated from the wiring pattern.

3. The circuit board according to claim 1, wherein
the lead terminal of the electronic component is soldered to the wiring pattern of the circuit board by dip soldering method while the lead terminal is inserted and mounted into the wiring pattern, thereby electrically connecting the wiring pattern to the electronic component, and
the through holes are arranged in a transport direction of the circuit board during soldering so that the through holes are not overlapped with an extension of the penetrating hole.

4. The circuit board according to claim 1, wherein
an overcoat is formed on a surface of the bump as the insulating layer, and
a surface of the overcoat is further covered with a silkscreened layer.

5. The circuit board according to claim 1, wherein
an extraction pattern, from which a resist layer and the wiring pattern formed on the circuit board are extracted, is formed around the penetrating hole to be located on the mounting surface on which the electronic component is mounted, and
ends of the extraction pattern are extended to an outside of the electronic component.

6. The circuit board according to claim 2, wherein
the lead terminal of the electronic component is soldered to the wiring pattern of the circuit board by dip soldering method while the lead terminal is inserted and mounted into the wiring pattern, thereby electrically connecting the wiring pattern to the electronic component, and
the through holes are arranged in a transport direction of the circuit board during soldering so that the through holes are not overlapped with an extension of the penetrating hole.

7. The circuit board according to claim 2, wherein
an overcoat is formed on a surface of the bump as the insulating layer, and
a surface of the overcoat is further covered with a silkscreened layer.

8. The circuit board according to claim 3, wherein
an overcoat is formed on a surface of the bump as the insulating layer, and
a surface of the overcoat is further covered with a silkscreened layer.

9. The circuit board according to claim 6, wherein
an overcoat is formed on a surface of the bump as the insulating layer, and
a surface of the overcoat is further covered with a silkscreened layer.

10. The circuit board according to claim 2, wherein
an extraction pattern, from which a resist layer and the wiring pattern formed on the circuit board are extracted, is formed around the penetrating hole to be located on the mounting surface on which the electronic component is mounted, and
ends of the extraction pattern are extended to an outside of the electronic component.

11. The circuit board according to claim 3, wherein
an extraction pattern, from which a resist layer and the wiring pattern formed on the circuit board are extracted, is formed around the penetrating hole to be located on the mounting surface on which the electronic component is mounted, and
ends of the extraction pattern are extended to an outside of the electronic component.

12. The circuit board according to claim 6, wherein
an extraction pattern, from which a resist layer and the wiring pattern formed on the circuit board are extracted, is formed around the penetrating hole to be located on the mounting surface on which the electronic component is mounted, and
ends of the extraction pattern are extended to an outside of the electronic component.

13. The circuit board according to claim 4, wherein
an extraction pattern, from which a resist layer and the wiring pattern formed on the circuit board are extracted, is formed around the penetrating hole to be located on the mounting surface on which the electronic component is mounted, and
ends of the extraction pattern are extended to an outside of the electronic component.

14. The circuit board according to claim 7, wherein
an extraction pattern, from which a resist layer and the wiring pattern formed on the circuit board are extracted, is formed around the penetrating hole to be located on the mounting surface on which the electronic component is mounted, and
ends of the extraction pattern are extended to an outside of the electronic component.

15. The circuit board according to claim 8, wherein
an extraction pattern, from which a resist layer and the wiring pattern formed on the circuit board are extracted, is formed around the penetrating hole to be located on the mounting surface on which the electronic component is mounted, and
ends of the extraction pattern are extended to an outside of the electronic component.

16. The circuit board according to claim 9, wherein
an extraction pattern, from which a resist layer and the wiring pattern formed on the circuit board are extracted, is formed around the penetrating hole to be located on the mounting surface on which the electronic component is mounted, and
ends of the extraction pattern are extended to an outside of the electronic component.
